(19) United States
(12) Patent Application Publication
(10) Pub. No.: US 2024/0247086 A1
(43) Pub. Date: Jul. 25, 2024

(54) Electromechanical Soft Actuator Driven by Low Voltage

(71) Applicant: The Regents of the University of California, Oakland, CA (US)

(72) Inventors: Raja ANNAPOORANAN, San Diego, CA (US); Yang WANG, San Diego, CA (US); Shengqiang CAI, San Diego, CA (US)

(21) Appl. No.: 18/482,471

(22) Filed: Oct. 6, 2023

Related U.S. Application Data
(60) Provisional application No. 63/378,855, filed on Oct. 7, 2022.

(51) Int. Cl. C08F 22/20; H02N 1/00

(52) U.S. Cl. CPC C08F 22/20; H02N 1/006

(57) ABSTRACT

Described are methods for manufacturing and using an electromechanical soft actuator including a dielectric liquid crystal elastomer. A method for manufacturing the electromechanical soft actuator including the dielectric liquid elastomer may include the steps of fabricating a loosely cross-linked polydomain liquid crystal elastomer, pre-stretching the loosely cross-linked polydomain liquid crystal elastomer on a frame, cross-linking elements of the loosely cross-linked polydomain liquid crystal elastomer to form the dielectric liquid crystal elastomer and removing the frame from the dielectric liquid crystal elastomer. The disclosed electromechanical soft actuator including the dielectric liquid crystal elastomer can be used in transducer for converting electrical energy to mechanical energy. The transducer may include at least two electrodes, and the dielectric liquid crystal elastomer, which has a first position that is deflected to a second position in response to a change in an electric field provided by the at least two electrodes.

### CROSS REFERENCE TO RELATED APPLICATIONS

This application claims the benefit of priority to U.S. Application No. 63/378,855 filed Oct. 7, 2022, the disclosure of which is incorporated by reference herein in its entirety.

### STATEMENT OF GOVERNMENT SUPPORT

This invention was made with government support under Grant Number W911NF-20-2-0182 awarded by the US Army Research Office. The government has certain rights in the invention.

### TECHNICAL FIELD

The present disclosure is directed towards an electromechanical actuator.

### BACKGROUND

An actuator is a device that produces a motion by converting energy and signals going into the system. Examples can be pneumatic, electrical, hydraulic actuators, and/or the like. A dielectric elastomer (DE) can be used as an electromechanical soft actuator and can be fabricated using rubber like materials that can deform under an electric field. In conventional systems, electromechanical actuators that use dielectric elastomers require input voltages in the range of 1000-10000 volts. This high input voltage presents an issue when it comes to commercial and/or practical applications of dielectric elastomers because high power amplifiers can increase the bulkiness of the device and result in lower energy efficiency. Accordingly, the widespread application of dielectric elastomers as electromechanical actuators is restricted by the high voltage requirement (1-10 kV) for thin film DEs, which increases the system complexity and pose a potential safety threat for humans.

### SUMMARY

In some example embodiments, there may be provided an electromechanical actuator including liquid crystal elastomers as substantially described and shown herein.

In an aspect, a method for manufacturing an electromechanical actuator including a dielectric liquid crystal elastomer includes the steps of fabricating a loosely cross-linked polydomain liquid crystal elastomer, pre-stretching the loosely cross-linked polydomain liquid crystal elastomer on a frame, cross-linking elements of the loosely cross-linked polydomain liquid crystal elastomer to form the dielectric liquid crystal elastomer, and removing the frame from the dielectric liquid crystal elastomer.

One or more of the following features can be included in any feasible combination. For example, fabricating the loosely cross-linked polydomain liquid crystal elastomer (LCE) may include reacting a liquid crystal monomer, a chain extender, and a cross-linker. In some examples, the liquid crystal monomer may include at least one of 1,4-Bis-[4-(3-acryloyloxypropyloxy)benzoyloxy]-2-methylbenzene, 4-(6-(acryloyloxy)hexyloxy)phenyl-4-(6-(acryloyloxy)hexyloxy)benzoate, 2-methyl-1,4-phenylene bis(4-((6-(acryloyloxy)hexyl)oxy)benzoate), 6-(4-Cyano-biphenyl-4′-yloxy)hexyl acrylate, [1-phosphono-2-(1-propylpyridin-2-yl)ethyl]phosphonic acid, and 4-Cyano-4′-pentylbiphenyl, 4-((6-hydroxyhexyl)oxy)phenyl 4-((6-hydroxyhexyl)oxy) benzoate, 4-(6-acryloyloxyhexyloxy)benzoic acid, 4,4′-diacrylolylhexyloxyazobenzene, 6-[4-(4-hexyloxyphenylazo)phenoxy]hexylacrylate, 4,4′-bis[6-(acryloyloxy)hexyloxy]azobenzene, (S)-1,4-Phenylene bis(4-((S)-6-(acryloyloxy)-3-methylhexyloxy)benzoate), 4,4′-Bis(11-(acryloyloxy)undecyloxy)azobenzene, 4,4′-Bis(3-(acryloyloxy)propyloxy)azobenzene, 4,4′-Bis(6-acryloyloxyhexyloxy)azobenzene, 4,4′-Bis(9-methacryloyloxy)nonyloxy)-azobenzene, 4,4′-Bis(9-(acryloyloxy)nonyloxy)azobenzene, 4,4′-Bis(6-methacryloyloxypropyloxy)azobenzene, E-1,2-Bis(4-hex-5-enyloxyphenyl)diazene, 4,4′-Bis(11-methacryloyloxy)undecyloxy)-azobenzene, 4,4′-Bis((6-methacryloyloxy)hexyloxy)azobenzene, 4-((4-(6-(Acryloyloxy)hexyloxy)phenoxy)carbonyl)phenyl 4-(6-(acryloyloxy)hexyloxy)benzoate, 1,4-Phenylene bis(4-(6-(acryloyloxy)hexyloxy)benzoate), 6-{4-[4-(Acryloyloxy-hexyloxy)cyclohexyl]phenoxyhexyl acrylate, 4-(6-(Acryloyloxy)hexyloxy)phenyl 4-(6-(acryloyloxy)hexyloxy)-2-methylbenzoate, 1,4-Bis[4-(11-acryloyloxyundecyloxy)benzoyloxy]-2-methylbenzene, 4-((4-(3-(Acryloyloxy)propoxy)phenoxy)carbonyl)phenyl 4-(3-(acryloyloxy)propoxy)benzoate, 2-Methyl-1,4-phenylene bis(4-(3-(allyloxy)propoxy)benzoate), 4-(6-(Acryloyloxy)hexyloxy)phenyl 4-(6-(acryloyloxy)hexyloxy)benzoate, 2-Methyl-1,4-phenylene bis(4-(oct-7-enyloxy)benzoate), 4-(4-(4-(11-(Acryloyloxy)undecyloxy)benzoyloxy)cyclohexyl)phenyl 4-(11-(acryloyloxy)undecyloxy)benzoate, 4-((4-(11-(Acryloyloxy)undecyloxy)phenoxy)carbonyl)phenyl 4-(11-(acryloyloxy)undecyloxy)benzoate, 4-(4-(11-(Acryloyloxy)undecyloxy)cyclohexanecarbonyloxy)phenyl 4-(11-(acryloyloxy)undecyloxy)benzoate, 2-Methyl-1,4-phenylene bis(4-(hex-5-enyloxy)benzoate), 1,4-Bis[4-(6-acryloyloxyhexyloxy)benzoyloxy]-2-methylbenzene, 1,4-Phenylene bis(4-(10-(acryloyloxy)decyloxy)benzoate), 1,4-Phenylene bis(4-(hex-5-enyloxy)benzoate), 1,4-Bis[4-(3-acryloyloxybutyloxy)benzoyloxy]-2-methylbenzene, 1,4-Bis[4-(11-acryloyloxyundecyloxy)benzoyloxy]benzene, Acrylic acid 6-[4′-(6-acryloyloxy-hexyloxy)biphenyl-4-yloxy]hexyl ester, or (E)-4′-(6-(Methacryloyloxy)hexyloxy)biphenyl-4-yl 3-(4-methoxyphenyl)acrylate. The chain extender can include at least one of 2,2′-(ethylenedioxy)diethanethiol, tetramethyldisiloxane, 1,5-diaminopentane, hexane-1,6-diyl diacrylate, bis(4-isocyanatophenyl)methane, polyethylene glycol, 1,2-ethanedithiol, 1,3-propanedithiol, 1,6-hexanedithiol, 1,9-nonanedithiol, 1,11-undecanedithiol, (ethylene glycol bis-(3-mercaptopropionate), 1,4-benzenedimethanethiol, Poly(ethylene glycol) diacrylate, 2,4,6-Triallyloxy-1,3,5-triazine, or glycol di(3-mercaptopropionate). The cross-linker can include at least one of pentaerythritoltetrakis(3-mercaptopropionate), trimethylolpropane tris(3-mercaptopropionate) (TMPMP), Trimethylolpropane Trimethacrylate (TMPTMA), Pentaerythritol Triacrylate (PETA), N,N′-Methylenebisacrylamide (MBAA), 1,4-butanediol diisocyanate (BDI), toluene diisocyanate (TDI), hexamethylene diisocyanate (HDI) and isophorone diisocyanate (IPDI), Triallyl isocyanurate (TAIC), tetraethyl orthosilicate (TEOS), hexamethylene diisocyanate trimer (HDI trimer), glycidyl methacrylate (GMA), 2,4,6,8-Tetramethyl-2,4,6,8-tetravinyl cyclotetrasiloxane (TMTVCTS), 2-ethyl-2-(hydroxymethyl)propane-1,3-diol, 1,6 hexandiol diacrylate, or (1,3,5-triallyl-1,3,5-triazine-2,4,6(1H,3H,5H)-trione. The ratio of the the liquid crystal monomer, the chain extender, to the cross-linker can be selected for a molar excess of acrylate groups. For example, the ratio of the liquid crystal monomer to the chain extender to the cross-linker can be about 105% to about 95% to about 5%, respectively.

Pre-stretching the loosely cross-linked polydomain liquid crystal elastomer on the frame can include equibiaxially stretching the loosely cross-linked polydomain liquid crystal elastomer. Additionally, or alternatively, pre-stretching the loosely cross-linked polydomain liquid crystal elastomer includes applying a uniaxial compression force. The frame may include plastic.

Cross-linking elements of the loosely cross-linked polydomain liquid crystal elastomer to form the dielectric liquid crystal elastomer may include applying UV-radiation to cross-link elements of the loosely cross-linked polydomain liquid crystal elastomer using a wavelength between about 100-400 nm, such that applying UV-radiation to excess acrylate groups within the loosely cross-linked polydomain liquid crystal elastomer fixes the alignment of elements of the loosely cross-linked polydomain liquid crystal elastomer. In some embodiments, cross-linking elements of the loosely cross-linked polydomain liquid crystal elastomer to form the dielectric liquid crystal elastomer further includes applying a thermal cross-linking initiator.

In some aspects, a transducer for converting electrical energy to mechanical energy can include at least two electrodes; and a dielectric liquid crystal elastomer having a first position that is deflected to a second position in response to a change in an electric field provided by the at least two electrodes. The dielectric liquid crystal elastomer can be fabricated by pre-stretching the loosely cross-linked polydomain liquid crystal elastomer on a frame, cross-linking elements of the loosely cross-linked polydomain liquid crystal elastomer to form the dielectric liquid crystal elastomer and removing the frame from the dielectric liquid crystal elastomer.

One or more of the following features can be include in any feasible combination. For example, the dielectric liquid crystal elastomer can include tensile strength between 1-10 MPa. Further, the ratio of the surface area of the first position to the surface area of the second position can be about 2. The dielectric liquid crystal elastomer can have a relative dielectric permittivity between about 2 and about 50, and the dielectric liquid crystal elastomer can have a thickness between about 10 and 1000 micrometers. In some embodiments, the electric field provided by the at least two electrodes can be generated by applying voltages less than about 400 volts. In some embodiments, the dielectric liquid crystal elastomer can be deflected from the second position to a third position in response to a second change in an electric field provided by the at least two electrodes. An electrode of the at least two electrodes can include carbon grease. Optionally, the transducer can be included in an artificial muscle, haptics, wearable devices, biomedical devices, robotics, power generation, adaptive optics, active braille displays, loudspeakers, deformable surfaces, energy harvesting, pumps, motors, and lightweight actuators.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

FIG. 1 illustrates a process for manufacturing an electromechanical soft actuator including a dielectric liquid crystal elastomer (DLCE), in accordance with some embodiments of the present disclosure.

FIG. 2 illustrates a schematic diagram for a process for manufacturing an electromechanical soft actuator including a dielectric liquid crystal elastomer (DLCE), in accordance with some embodiments of the present disclosure.

FIG. 3 illustrates properties for a polydomain liquid crystal elastomer (LCE), in accordance with some embodiments of the present disclosure.

FIG. 4 illustrates properties of a dielectric liquid crystal elastomer (DLCE), in accordance with some embodiments of the present disclosure.

FIG. 5A illustrates properties of a dielectric liquid crystal elastomer (DLCE), in accordance with some embodiments of the present disclosure.

FIG. 5B illustrates properties of a dielectric elastomer for comparison with some embodiments of the present disclosure.

FIG. 5C illustrates properties of a dielectric liquid crystal elastomer (DLCE), in accordance with some embodiments of the present disclosure.

FIG. 5D illustrates properties of a dielectric elastomer for comparison with some embodiments of the present disclosure.

FIG. 5E illustrates properties of a dielectric liquid crystal elastomer (DLCE), in accordance with some embodiments of the present disclosure.

FIG. 5F illustrates properties of a dielectric elastomer for comparison with some embodiments of the present disclosure.

FIG. 6A illustrates properties for a dielectric liquid crystal elastomer (DLCE) used as an electromechanical actuator, in accordance with some embodiments of the present disclosure.

FIG. 6B provides a first photograph for a dielectric liquid crystal elastomer (DLCE) used as an electromechanical actuator at 0 Volts, in accordance with some embodiments of the present disclosure.

FIG. 6C provides a first photograph for a dielectric liquid crystal elastomer (DLCE) used as an electromechanical actuator at 300 Volts, in accordance with some embodiments of the present disclosure.

FIG. 7A provides a first photograph for a dielectric liquid crystal elastomer (DLCE) used as an electromechanical actuator at 0 Volts, in accordance with some embodiments of the present disclosure.

FIG. 7B provides a second photograph for a dielectric liquid crystal elastomer (DLCE) used as an electromechanical actuator at 300 Volts, in accordance with some embodiments of the present disclosure.

FIG. 8A provides a first photograph for a dielectric liquid crystal elastomer (DLCE) used as a soft tunable lens at 0 Volts, in accordance with some embodiments of the present disclosure.

FIG. 8B provides a second photograph for a dielectric liquid crystal elastomer (DLCE) used as a soft tunable lens at 500 Volts, in accordance with some embodiments of the present disclosure.

FIG. 8C provides a characterization of properties of the dielectric liquid crystal elastomer (DLCE) used as a soft tunable lens, in accordance with some embodiments of the present disclosure.

FIG. 9A provides a first photograph for a dielectric liquid crystal elastomer (DLCE) used as a diaphragm actuator at 100 Volts, in accordance with some embodiments of the present disclosure.

FIG. 9B provides a second photograph for a dielectric liquid crystal elastomer (DLCE) used as a diaphragm actuator at 200 Volts, in accordance with some embodiments of the present disclosure.

FIG. 9C provides a third photograph for a dielectric liquid crystal elastomer (DLCE) used as a diaphragm actuator at 300 Volts, in accordance with some embodiments of the present disclosure.

FIG. 9D provides a fourth photograph for a dielectric liquid crystal elastomer (DLCE) used as a diaphragm actuator at 400 Volts, in accordance with some embodiments of the present disclosure.

### DETAILED DESCRIPTION

An electromechanical actuator is described herein. In some embodiments, the electromechanical actuator may be fabricated using liquid crystal elastomers (LCEs). Liquid crystal elastomers combine unique properties of liquid crystals and rubbers. Using LCEs, the disclosed electromechanical actuators are able to provide a dielectric elastomer actuator that can be operated at substantially low voltage compared to conventional dielectric elastomer actuators. For example, the electromechanical actuators described herein can be operated at less than 300 volts. Further, the electromechanical actuator described herein can be operated without a secondary support structure or rigid frame.

The dielectric elastomer actuators using liquid crystal elastomers (DLCEs) described herein have soft elasticity and a high dielectric constant, both of which can be utilized to reduce the actuation voltage. The manufacturing techniques described herein allow for fabrication of freestanding DLCE thin film actuators (e.g., approximately 20 μm) that can generate large actuation strains (approximately 88%) at 400 V, an input voltage almost one order of magnitude lower compared to conventional dielectric elastomers actuators. The disclosed soft electromechanical transducers can generate large, rapid, and reversible deformation under an electric field.

Conventional dielectric elastomer actuators were unable to attain large actuation strains, due to electromechanical instability (EMI) or pull-in effect, where the applied electric field triggers a feedback loop of thinning down the DE film and causes failure by electrical breakdown. In prior dielectric elastomer actuators, pre-stretching the elastomer would modify the mechanical behavior of the film resulting in rapid strain-stiffening and thereby suppressing electromechanical instability. Additionally, the rigid frame necessary to maintain the pre-stretch in prior designs, restricted the design space and lowered the lifetime of the actuators.

While some prior systems used various synthetic techniques to tune the onset of strain stiffening of the elastomer network and eliminate EMI, these techniques typically increase the modulus and result in a high applied electric field (50-100 V μm⁻¹). To reduce the applied electric field, some prior systems increased the dielectric permittivity of the elastomer by adding high permittivity ceramic fillers or by modifying the functional groups in the backbone of the elastomer, but these modifications increased the modulus or require complex chemical synthesis. While using ultra-thin elastomer films can bring down the input voltage to an extent, it requires complicated fabrication and handling.

To address these issues, prior solutions included bottlebrush elastomers controlled the molecular architecture by synthesis and were able to achieve a low initial modulus and stiffening at small strain, generating large actuation strains at applied fields of 1-10 V μm⁻¹. But the low tensile strength (10-100 kPa) of these bottlebrush elastomers made it challenging to fabricate thin film actuators (<100 μm), which can be operated at low voltages (<500 V).

Prior usage of LCEs as an actuator were further limited by the rate of heat transfer, the fact that they are energetically inefficient, and that their use can lead to premature heat induced rupture. Indeed, previously reported electromechanical actuation of liquid crystal elastomers are limited by either low actuation strains or the high input electric fields.

Accordingly, there remained a need for a freestanding actuator with sufficient tensile strength, which could be operated at low electric field can enable various applications, especially in biomedical and wearable devices where the high input voltage can be a safety concern. For example, in robotic devices, the high voltage amplifiers consume most of the energy and increase the overall bulkiness.

The present disclosure utilizes liquid crystal elastomers (LCEs) and combines the long range orientational order of liquid crystal monomers or mesogens and the elasticity of polymer networks, resulting in several unique properties. The disclosed dielectric elastomer actuators using liquid crystal elastomers (DLCEs) can undergo large deformation with a small mechanical work, also known as soft elasticity. As a result of mesogen rotation, or changes in the orientational order of liquid crystal monomers, the DLCEs can reversibly deform and perform work by using an electric field.

Disclosed herein is a liquid crystal based dielectric elastomer actuator that can be operated at a low voltage, such as at a voltage at or below 300 volts, 100 volts, or less.

Conventional dielectric elastomers based on acrylic and silicone elastomers, typically require voltages in the order of 1000-10000 volts, and may require a rigid frame to function. In some embodiments, the disclosed liquid crystal based dielectric elastomer can be operated at a much lower voltage of for example 300V (or even lower as noted above) without any rigid frames, providing numerous advantages.

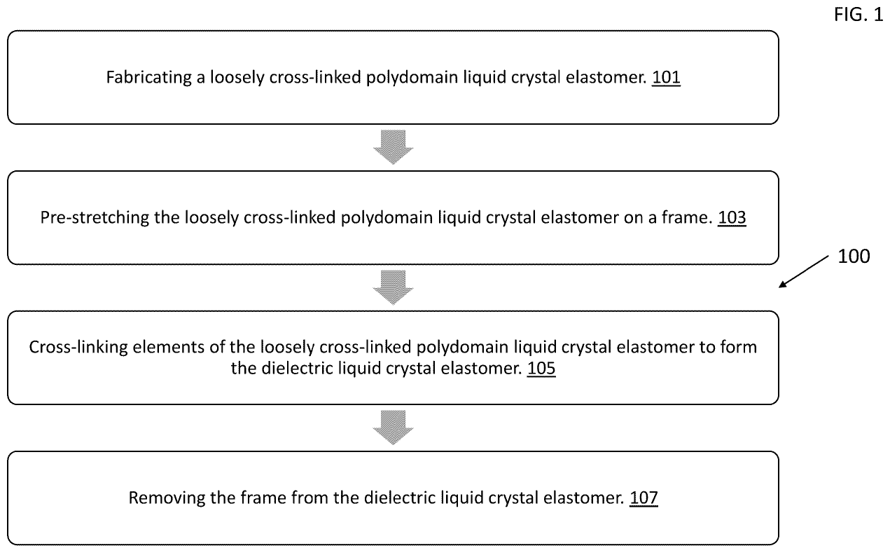

FIG. 1 illustrates a process 100 for manufacturing an electromechanical soft actuator including a dielectric liquid crystal elastomer (DLCE). Dielectric liquid crystal elastomers (DLCEs) can be fabricated to form thin film dielectric elastomer actuators which exhibit electromechanical instability-free electroactuation at low electric fields, due to the combination of one or more of: pre-stretching, soft-elasticity, cross-linking, and a high relative dielectric permittivity. As will be discussed below, pre-stretching such as biaxial pre-stretching or uni-axial compression can result in the strain stiffening of the LCE network which eliminates electromechanical instability. Further, this may result in the low modulus of LCE after pre-stretching. Additionally, the crosslinking step discussed below allows the pre-stretch to be maintained without the requirement of external frames. Additionally, the high relative dielectric permittivity contributes to the actuation of the DLCE thin film at low electric fields.

As illustrated in a first step 101 a loosely cross-linked polydomain liquid crystal elastomer is fabricated. A thiol-acrylate addition reaction to prepare a loosely crosslinked LCEs. For example, fabricating the loosely cross-linked polydomain liquid crystal elastomer (LCE) may include the reaction of a liquid crystal monomer, a chain extender, and a cross-linker. The loosely cross-linked polydomain LCE may have short range order (micrometer sized domains) but no global order.

A liquid crystal monomer may include a liquid crystal material having a terminal group which is polymerizable by the action of a UV-sensitive photo initiator or a heat triggered thermal initiator. The liquid crystal material can be configured to undergo addition or condensation reactions with other chemicals. Liquid crystal monomers can include acrylate terminated liquid crystal monomers and the like. Examples of liquid crystal monomers include, but are not limited to, 1,4-Bis-[4-(3-acryloyloxypropyloxy)benzoyloxy]-2-methylbenzene (RM257),4-(6-(acryloyloxy)hexyloxy)phenyl-4-(6-(acryloyloxy)hexyloxy)benzoate (C6BAPE), 2-methyl-1,4-phenylene bis(4-((6-(acryloyloxy)hexyl)oxy)benzoate) (RM82), 6-(4-Cyano-biphenyl-4′-yloxy)hexyl acrylate (A60CB), [1-phosphono-2-(1-propylpyridin-2-yl)ethyl]phosphonic acid (C6M), and 4-Cyano-4′-pentylbiphenyl (5CB), 4-((6-hydroxyhexyl)oxy)phenyl 4-((6-hydroxyhexyl)oxy)benzoate, 4-(6-acryloyloxyhexyloxy)benzoic acid, 4,4′-diacrylolylhexyloxyazobenzene, 6-[4-(4-hexyloxyphenylazo)phenoxy]hexylacrylate, 4,4′-bis[6-(acryloyloxy)hexyloxy]azobenzene, (S)-1,4-Phenylene bis(4-((S)-6-(acryloyloxy)-3-methylhexyloxy)benzoate), 4,4′-Bis(11-(acryloyloxy)undecyloxy)azobenzene, 4,4′-Bis(3-(acryloyloxy)propyloxy)azobenzene, 4,4′-Bis(6-acryloyloxyhexyloxy)azobenzene, 4,4′-Bis(9-methacryloyloxy)nonyloxy)-azobenzene, 4,4′-Bis(9-(acryloyloxy)nonyloxy)azobenzene, 4,4′-Bis(6-methacryloyloxypropyloxy)azobenzene, E-1,2-Bis(4-hex-5-enyloxyphenyl)diazene, 4,4′-Bis(11-methacryloyloxy)undecyloxy)-azobenzene, 4,4′-Bis((6-methacryloyloxy)hexyloxy)azobenzene, 4-((4-(6-(Acryloyloxy)hexyloxy)phenoxy)carbonyl)phenyl 4-(6-(acryloyloxy)hexyloxy)benzoate, 1,4-Phenylene bis(4-(6-(acryloyloxy)hexyloxy)benzoate), 6-{4-[4-(Acryloyloxy-hexyloxy)cyclohexyl]phenoxyhexyl acrylate, 4-(6-(Acryloyloxy)hexyloxy)phenyl 4-(6-(acryloyloxy)hexyloxy)-2-methylbenzoate, 1,4-Bis[4-(11-acryloyloxyundecyloxy)benzoyloxy]-2-methylbenzene, 4-((4-(3-(Acryloyloxy)propoxy)phenoxy)carbonyl)phenyl 4-(3-(acryloyloxy)propoxy)benzoate, 2-Methyl-1,4-phenylene bis(4-(3-(allyloxy)propoxy)benzoate), 4-(6-(Acryloyloxy)hexyloxy)phenyl 4-(6-(acryloyloxy)hexyloxy)benzoate, 2-Methyl-1,4-phenylene bis(4-(oct-7-enyloxy)benzoate), 4-(4-(4-(11-(Acryloyloxy)undecyloxy)benzoyloxy)cyclohexyl)phenyl 4-(11-(acryloyloxy)undecyloxy)benzoate, 4-((4-(11-(Acryloyloxy)undecyloxy)phenoxy)carbonyl)phenyl 4-(11-(acryloyloxy)undecyloxy)benzoate, 4-(4-(11-(Acryloyloxy)undecyloxy)cyclohexanecarbonyloxy)phenyl 4-(11-(acryloyloxy)undecyloxy)benzoate, 2-Methyl-1,4-phenylene bis(4-(hex-5-enyloxy)benzoate), 1,4-Bis[4-(6-acryloyloxyhexyloxy)benzoyloxy]-2-methylbenzene, 1,4-Phenylene bis(4-(10-(acryloyloxy)decyloxy)benzoate), 1,4-Phenylene bis(4-(hex-5-enyloxy)benzoate), 1,4-Bis[4-(3-acryloyloxybutyloxy)benzoyloxy]-2-methylbenzene, 1,4-Bis[4-(11-acryloyloxyundecyloxy)benzoyloxy]benzene, Acrylic acid 6-[4′-(6-acryloyloxy-hexyloxy)biphenyl-4-yloxy]hexyl ester, (E)-4′-(6-(Methacryloyloxy)hexyloxy)biphenyl-4-yl 3-(4-methoxyphenyl)acrylate.

Further, examples of chain extenders include but are not limited to 2,2′-(ethylenedioxy)diethanethiol (EDDET), tetramethyldisiloxane, 1,5-diaminopentane, hexane-1,6-diyl diacrylate, bis(4-isocyanatophenyl)methane, polyethylene glycol, 1,2-ethanedithiol, 1,3-propanedithiol, 1,6-hexanedithiol, 1,9-nonanedithiol, 1,11-undecanedithiol, (ethylene glycol bis-(3-mercaptopropionate), 1,4-benzenedimethanethiol, Poly(ethylene glycol) diacrylate, and 2,4,6-Triallyloxy-1,3,5-triazine, glycol di(3-mercaptopropionate).

Additionally, examples of cross-linkers include, but are not limited to, at least one of pentaerythritoltetrakis(3-mercaptopropionate) (PETMP), Trimethylolpropane tris(3-mercaptopropionate) (TMPMP), Trimethylolpropane Trimethacrylate (TMPTMA), Pentaerythritol Triacrylate (PETA), N,N′-Methylenebisacrylamide (MBAA), 1,4-butanediol diisocyanate (BDI), toluene diisocyanate (TDI), hexamethylene diisocyanate (HDI) and isophorone diisocyanate (IPDI), Triallyl isocyanurate (TAIC), tetraethyl orthosilicate (TEOS), hexamethylene diisocyanate trimer (HDI trimer), glycidyl methacrylate (GMA), 2,4,6,8-Tetramethyl-2,4,6,8-tetravinyl cyclotetrasiloxane (TMTVCTS), 2-ethyl-2-(hydroxymethyl)propane-1,3-diol, and 1,6 hexandiol diacrylate, (1,3,5-triallyl-1,3,5-triazine-2,4,6(1H,3H,5H)-trione.

Many combinations of a liquid crystal monomer, chain extender and crosslinkers can be used for the formation of a crosslinked liquid crystal elastomer network. The liquid crystal monomers can include nematic, smectic, chiral, discotic, bent-core, fluorinated, thermotropic and lyotropic liquid crystal monomers and the like. The chain extender and crosslinkers can possess various functional groups such as thiols, silicones, silane coupling agents, acrylates, polyurethanes, diols, triols, isocyanates, hydroxy-functionalized compounds, epoxides, diacrylates, dimethacrylates, polyamines, alkenes, hydrazines, and carboxylic acid-terminated compounds.

Although some liquid crystal monomers, chain extenders, and cross-linkers are described herein it is contemplated that alternative liquid crystal monomers, chain extenders, and/or cross-linkers which promote electrical activity can be used.

In some embodiments the ratio of the reagents including liquid crystal monomer, chain extender, and cross-linker can be selected for a molar excess of acrylate groups. For example, in an exemplary embodiment the ratio of the liquid crystal monomer to the chain extender to the cross-linker can be about 105% to about 95% to about 5%, respectively. The ratio between liquid crystal monomer, chain extender and crosslinker can be varied between 0-100% to obtain the desired electromechanical response.

Fabricating the loosely cross-linked polydomain liquid crystal elastomer (LCE) in step 101 may include a Michael addition followed by photoinitiated free radical polymerization. For example, in some embodiments, a liquid crystal monomer such as RM257 (10 g, 16.98 mmol) can be dissolved in Toluene (3.15 g) at 85° C. A chain-extender such as EDDET (2.8022 g, 15.37 mmol), a crosslinker such as PETMP (0.1976 g, 0.405 mmol), a catalyst such as dipropylamine (0.03441 g, 0.34 mmol) and a photoinitiator such as (2-hydroxyethoxy)-2-methylpropiophenone (0.06406 g, 0.285 mmol) can be added to the mixture of the liquid crystal monomer in Toluene. The resulting mixture can be stirred and degassed. In some embodiments, the resulting mixture may correspond to a mol % ratio of RM257/EDDET/PETMP=105%/95%/5%. The resulting mixture can be poured in a glass mold and left for 12 hours at room temperature for the first stage of a crosslinking reaction to conclude. Then resulting loosely crosslinked LCE film can then be placed in an oven at a time and temperature suitable to evaporate the solvent. For example, in some embodiments, the loosely cross-linked LCE film can be placed in an oven at 85° C. for 24 hours to evaporate the solvent.

In a second step 103, the loosely cross-linked polydomain liquid crystal elastomer is pre-stretched on a frame. In some embodiments, the frame may be composed of or include plastic or other similar materials.

For example, in some embodiments, the loosely cross-linked polydomain liquid crystal elastomer can be equi-biaxially stretched and attached to a circular plastic frame. In some embodiments the loosely cross-linked polydomain liquid crystal elastomer can be reversibly attached to the frame using any suitable adhesive (e.g., double sided tape). The pre-stretch (λₚ) during synthesis is given by λₚ=r/R, where R is the initial radius of the sample and r is the final radius of the sample. An applied pre-stretch between 1<λₚ<3, does not create a homogeneous transparent LCE film. To create a homogenous transparent LCE film a pre-stretch λₚ greater than or equal to 3 can be used. In some embodiments, a biaxial pre-stretch λₚ of between about 3 to 4 can be used. In some embodiments a pre-stretch λₚ range of between about 1.1 to 10 can be used depending on the chemistry of the components used to form the polydomain liquid crystal elastomer. For example, in some embodiments a force of 1 Newton can be applied biaxially to the polydomain liquid crystal elastomer film having a 20 micrometer thickness.

In another example, in some embodiments, a uniaxial compressive force can be used to pre-stretch the loosely cross-linked polydomain liquid crystal elastomer. Instead of applying a biaxial pre-stretch using tension or pulling, a uniaxial compressive force can also be used.

Pre-stretching, including by a biaxial pre-stretch or uniaxial compression can modify the electromechanical properties of the loosely cross-linked polydomain liquid crystal elastomer fabricated in step 101. For example, pre-stretching can improve the strain-stiffening of the elastomer which can prevent failure due to electromechanical instability and thereby increasing the output actuation strain and output actuation force. Further, pre-stretching can align the liquid crystals within the loosely cross-linked polydomain liquid crystal elastomer such that it increases the relative dielectric permittivity of the liquid crystal elastomer. Additionally, pre-stretching allows for a reduction in the thickness of the overall film and thereby reduces the applied voltage needed for actuation. Pre-stretching can allow for combination of all the above mentioned properties without sacrifice of one of the electromechanical properties.

In a third step 105, elements of the loosely cross-linked polydomain liquid crystal elastomer are cross-linked to form the dielectric liquid crystal elastomer.

For example, UV-radiation can be applied to the pre-stretched loosely cross-linked polydomain liquid crystal elastomer so as to form the dielectric liquid crystal elastomer. UV-radiation can be applied to cross-link elements of the loosely cross-linked polydomain liquid crystal elastomer in a wavelength between about 300-400 nm for 15 minutes on each side. The wavelength can be determined by the type of photo initiator and can vary from 100-1100 nm. The duration of the UV radiation can be increased or decreased depending on the thickness of the elastomer. For example, the UV radiation may be applied for 30 minutes on each side for an elastomer of higher thickness to ensure sufficient reaction. The UV-radiation can be applied to excess acrylate groups within the loosely cross-linked polydomain liquid crystal elastomer to permanently fix the alignment of elements of the loosely cross-linked polydomain liquid crystal elastomer.

For example, in some embodiments, after stretching, the loosely cross-linked polydomain liquid crystal elastomer film on the frame can be placed under a UV lamp (365 nm, 100 W) for 15 minutes on each side, to complete the crosslinking reaction.

In some embodiments, the third step 105, may require the application of a thermal initiator compound. For example, a thermal initiator such as azobisisobutyronitrile can be used to initiate the crosslinking of excess acrylate groups using heat energy. Alternatively, by using two orthogonal polymer reactions with varying reaction times, a loosely crosslinked network can be formed using the faster first reaction, pre-stretched and held for more time for the second polymer reaction to be completed.

In a fourth step 107, the frame may be removed from the dielectric liquid crystal elastomer. For example, in some embodiments, after the UV crosslinking, the resulting dielectric liquid crystal elastomer film was left on the frame for one hour to allow any relaxation and then it was removed from the frame. In some embodiments, the frame may be removed by a manual process (i.e., tweezers) or automatic process.

In some embodiments, the process described in FIG. 1 can be adapted for other combinations of liquid crystal monomers, chain-extenders and crosslinkers, in order to achieve specific applications.

The process described in 100 can be used to manufacture freestanding dielectric liquid crystal elastomer actuators that possess low modulus, early strain stiffening, good tensile strength (1-10 MPa), high relative dielectric permittivity (>25). Accordingly, electromechancial actuators using DLCEs may result in the generation of large EMI-free actuation strains (≈88%) at low electric fields (≈20 V μm⁻¹). Thin film electromechancial actuators (≈20 μm) of different geometries can be generated, all of which can be operated at low voltages (<400 V).

The process described in 100 can be used to manufacture DLCEs that possess unique stress-strain behavior, due to the coupling between the rotation of liquid crystal mesogens and the deformation of polymer network. The biaxial pre-stretching in step 103 can result in strain-stiffening that eliminates the EMI. In some embodiments, the pre-stretching in step 103 can allow for the tailoring of the onset of the strain-stiffening without significantly increasing the modulus. Further, the force required to maintain the pre-stretch in step 103 can be lower than that in conventional elastomers. Thus, a cross-linking step 105 can be used to permanently fix the pre-stretch. Accordingly, the process 100 can result in a free-standing LCE film that exhibits EMI-free stable electro-actuation.

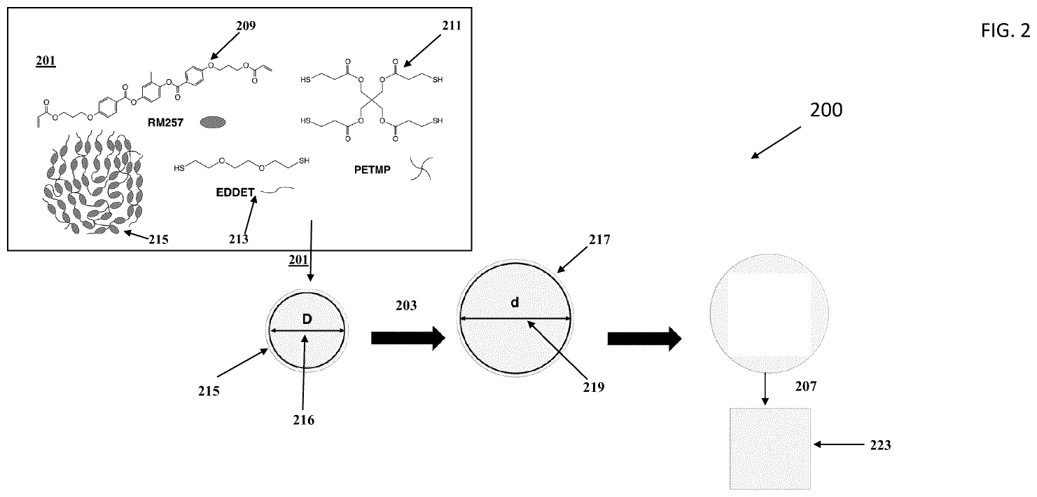

FIG. 2 provides a schematic overview 200 of the process 100 illustrated in FIG. 1. As shown, in a first step 201 a polydomain LCE is fabricated from a liquid crystal monomer such as RM257 209, chain extender EDDET 213, and crosslinker PETMP 211. As illustrated, the resulting polydomain LCE 215 may be loosely cross-linked. The polydomain LCE 215 may be fabricated with a first diameter D 216. In a second step 203, the polydomain LCE is pre-stretched on a frame 217 as the diameter of the polydomain LCE 215 is expanded to d 219. In a third step 205, UV-radiation is applied to the pre-stretched polydomain LCE to cross-link the stretched elements of the polydomain LCE 215. In a fourth step 207, the frame 217 is removed to leave a freestanding DLCE 223.

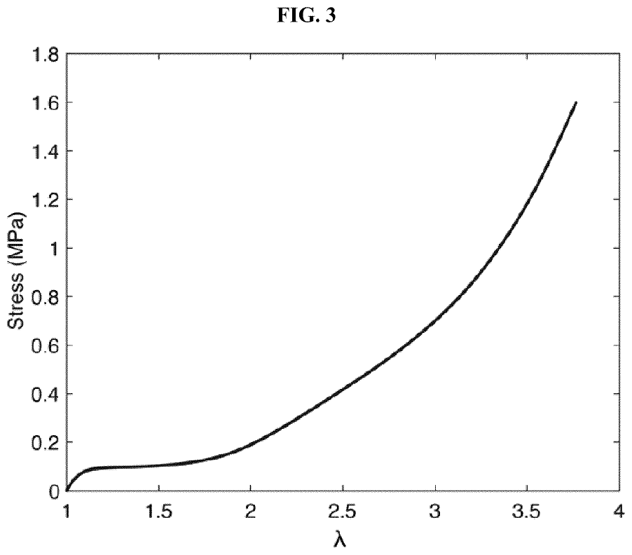

FIG. 3 provides a characterization of the properties of the polydomain LCE that is fabricated in step 101 and 201 of the processes 100 and 200 of FIGS. 1 and 2, respectively. FIG. 3 illustrates a uniaxial stress-strain curve of a free standing polydomain LCE. As shown, there is a stress plateau of soft elasticity between a prestretch value λₚ=1.2 to 1.8.

A DLCE fabricated in accordance with the process discussed in FIGS. 1 and 2 can be characterized based on at least its stress-strain curve, relative dielectric permittivity, pure shear actuation, and diaphragm actuation.

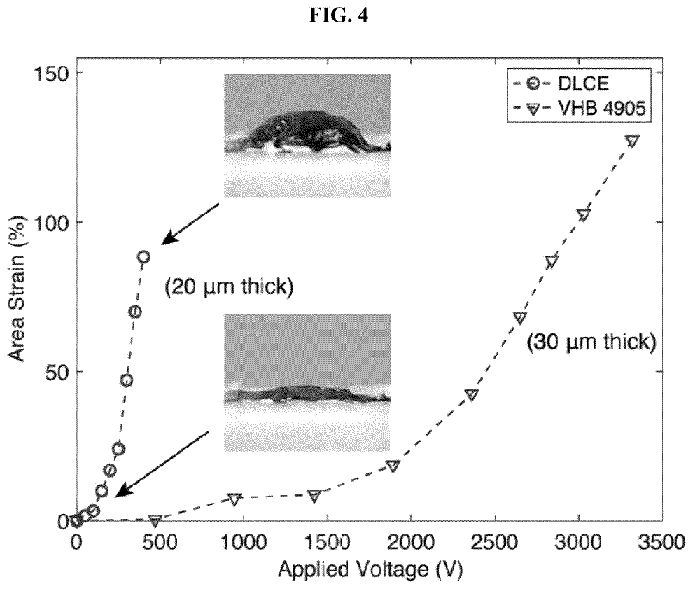

For example, FIG. 4 provides a characterization of the properties of the freestanding DLCE resulting from the manufacturing process described in FIGS. 1 and 2. In particular, FIG. 4 illustrates the actuation strain of DLCE at various applied voltages. The electro-actuation behavior of a DLCE having 20 microns of thickness is illustrated. The electro-actuation behavior of the DLCE is contrasted with a biaxially pre-stretched conventional dielectric actuator VHB of 30 microns. As shown, the DLCE sample can achieve=88% strain at 400 V (nominal field=20 V μm⁻¹), while a high applied voltage >2500 V is required to actuate the VHB 4905 thin film to a similar strain (nominal field=90 V μm⁻¹).

In some embodiments, the data displayed in FIG. 4 can be generated using pure shear tensile tests conducted on the DLCE using Universal Mechanical Testing System (5965 Dual Column Testing System, Instron) with a 5-kN load cell. Rectangular samples (e.g., height of approximately 5 mm and width of approximately 50 mm) of the DLCE can be glued onto acrylic plates and held between the tensile grippers. The applied stretch (A) can be defined as λ=h/H, where H is the height of the sample in the undeformed state and h is the height of the sample in the deformed state. The nominal stress can be calculated by dividing the force by the original cross-sectional area of the sample. A loading rate of 0.001 s⁻¹ can be used for the tests. The small-strain modulus can be measured at 1% strain. The secant modulus can be measured at 25% strain. A pure shear tensile test for a DLCE can be compared to that for pre-stretched VHB samples. For example, VHB samples can be stretched using a vertical pre-stretch using the tensile tester before the test, and a horizontal pre-stretch fixed by the rectangular acrylic plates. For visualization purposes, the data from the tensile tests can be smoothed prior to display of a stress-strain curve.

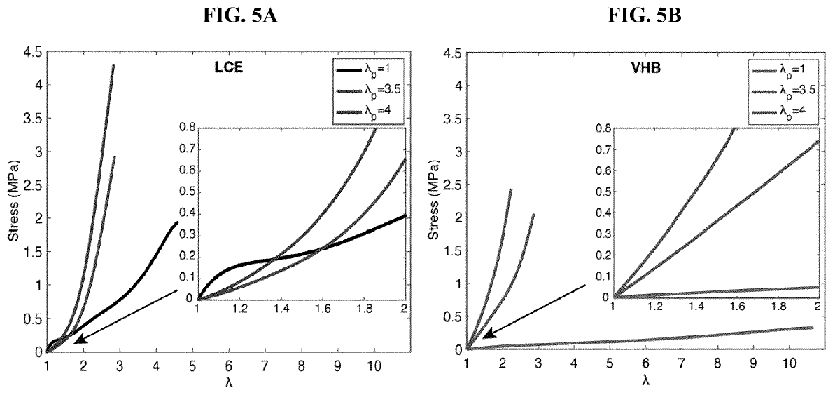

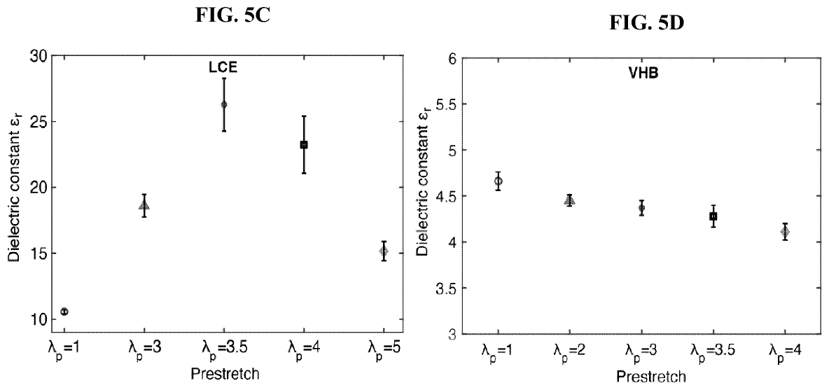

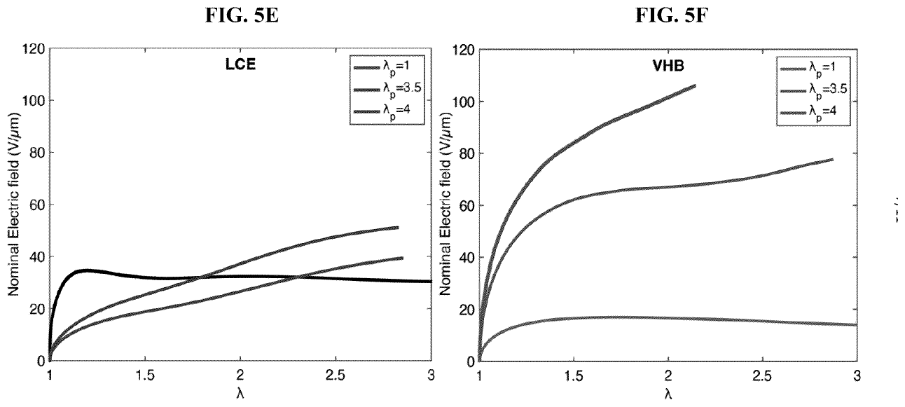

In another example, FIGS. 5A-5F illustrate various characterizing properties of the DLCE in comparison with prior techniques (e.g., acrylic based dielectric elastomer actuator VHB).

FIG. 5A illustrates stress-strain curves for a rectangular (pure shear) DLCE sample, subjected to various pre-stretch during manufacturing (λₚ). As shown, the polydomain LCE sample without any pre-stretch (λₚ=1), demonstrates an initial increase in stress, with a small strain modulus of 2 MPa (measured at 1% strain), then a small plateau, which is followed by further increase in stress till rupture. For a pre-stretch of λₚ=3.5 and 4, the small strain modulus is 0.7 and 1.1 MPa, respectively and the stress-strain curve takes a J shape, showing rapid strain stiffening. This J-shaped tensile curve, which is also observed in many biological materials, is particularly advantageous for dielectric elastomers, as the strain-stiffening can eliminate electromechanical instability (EMI).

For comparison, the stress-strain curves of pure shear conventional dielectric actuator VHB samples is shown in FIG. 5B. As illustrated, strain-stiffening is seen after pre-stretching. However, this comes at the cost of increase in the small-strain modulus from 0.3 MPa without pre-stretch, to 0.8 MPa and 1.3 MPa for λₚ=3.5 and λₚ=4, respectively.

As is illustrated by comparing FIGS. 5A and 5B, for both polydomain LCE and VHB, higher pre-stretch results in earlier onset of strain stiffening. However, the value of secant modulus measured at 25% strain, showed a small reduction for LCE (0.68-0.41 MPa) compared to the drastic change for VHB (0.14-1.2 MPa) as the pre-stretch is increased from λₚ=1 and λₚ=4. This shows that the disclosed DLCES have a combination of soft-elasticity and pre-stretching which results in the desired stress-strain curve with low modulus, rapid strain-stiffening, and good tensile strength when compared to VHB.

FIG. 5C provides a graph of the relative dielectric permittivity (εᵣ) of the DLCE samples. As shown, the relative dielectric permittivity (εᵣ) of DLCE samples illustrate a non-linear dependence with the applied pre-stretch. The relative dielectric permittivity increases from εᵣ≈10.5 with no pre-stretch (λₚ=1), to a maximum of εᵣ≈26.5 at λₚ=3.5 and decreases with higher pre-stretch. The DLCE samples also show a loss tangent ≈0.05 at 100 Hz.

The relative dielectric permittivity measurements in FIGS. 5C and 5D can be measured as using a digital thickness gauge (Mitutoyo). For example, conductive silver paste can be used as the electrode and used to coat both the sides of the DLCE film. The capacitance can then be measured using an LCR meter (Keysight E4980A) at 1 V from 20 Hz to 1 MHz frequencies. The relative dielectric permittivity can be calculated by

$${ε}_{r} = \frac{Cz}{{ε}_{0} A} ,$$

where C is the measured capacitance, z is the thickness of the DLCE film, εₒ is the permittivity of free space, and A is the area of the electrodes. In some embodiments, the silver paste electrodes can be replaced with carbon grease electrodes.

FIG. 5D provides a graph of the relative dielectric permittivity (εᵣ) of the VHB samples. As illustrated, the VHB 4905 sample possesses a relative dielectric permittivity of εᵣ≈4.6 and increasing the pre-stretch results in the slight reduction of εᵣ.

As illustrated in a comparison of FIGS. 5C and 5D, the DLCE is associated with a relatively high dielectric permittivity and a non-linear dependence on the applied stretch. In addition to its use in actuators, this property can be used for applications such as energy storage and harvesting.

FIG. 5E illustrates the relationship between the applied voltage and actuation strain for DLCE in the pure shear configuration. Similarly, FIG. 5F illustrates the relationship between the applied voltage and actuation strain for the VHB in the pure shear configuration. Data for FIGS. 5E and 5F can be determined based on the measured stress-strain relationship (illustrated in FIGS. 5A, 5B) and dielectric constants corresponding to the pre-stretch (illustrated in FIGS. 5C and 5D). As illustrated in FIGS. 5E and 5F, samples without pre-stretch (λₚ=1), reach a maximum around λ=1.25 and experience EMI. Pre-stretch results in strain-stiffening, which generates a monotonically increasing voltage-actuation curve without EMI. For most elastomers, pre-stretch makes the strain stiffening occur earlier which can avoid EMI, however it also increases the stiffness significantly as shown in FIG. 5B inset. As shown in FIG. 5F, in the case of pre-stretched VHB, the increased stiffness and the relatively lower values of relative dielectric permittivity, result in high input electric field above 50 V μm⁻¹. On the other hand, as shown in FIG. 5E, the combination of low modulus enabled by soft-elasticity, early strain stiffening, and the high dielectric constant of DLCE, results in the EMI free actuation at a low electric field of 20 V μm⁻¹. Pre-stretching during synthesis also results in the reduction of thickness, hence a polydomain LCE film with an initial thickness of approximately 250 μm can yield thin films of approximately 20 μm after pre-stretching (λₚ=3.5).

In some embodiments, the electro-actuation behavior of an elastomer can be predicted based on an ideal dielectric elastomer assumption. For example, an incompressible material (λ₁λ₂λ₃=1) under pure-shear configuration (λ₂=1), can be expressed with stress-strain curve as σ=f(λ). An applied electric field will generate a Maxwell stress equal to εE². Thus,

$${}^{E = \frac{Φ}{h}} ε {E}^{2} = {f ( λ )}^{\frac{h}{H} = {λ}^{- 1}}$$

Further, the electric field can be related to the applied voltage as: E=Φ/h, where his the thickness of the film after deformation. Due to the incompressibility, the thickness change of the film after and before deformation is h/H=λ⁻¹. As a result, we have the relationship between the applied voltage and the deformation:

$$Φ = \frac{H}{\sqrt{ε}} {λ}^{- 1} \sqrt{f ( λ )} .$$

In some embodiments, a DLCE fabricated according to the process illustrated in FIGS. 1 and 2 can be used as an actuator. After a thin film of the DLCE is synthesized in accordance with the process illustrated in FIGS. 1 and 2, the material can be sandwiched between a positive electrode and a negative electrode. In some embodiments, the thin film may be approximately 20-50 microns thick. In some embodiments, the positive and negative electrodes may be compliant and/or stretchable.

For example, the electrodes may be composed of carbon grease, silver, carbon nanotubes, graphite powder, graphene, metallic nanowires, ionic hydrogels, conductive polymers, liquid metal alloys, conductive fabrics, or the like. For example, conductive polymers may include polyaniline, polythiophene, and PEDOT:PSS (poly(3,4-ethylenedioxythiophene): poly(styrenesulfonate)). Liquid metal alloys can include gallium-based alloys (e.g., gallium-indium-tin) and the like. Conductive fabrics can be made from materials like knitted or woven metallic threads, or coated with conductive nanoparticles. Ink formulations containing carbon nanomaterials like graphene or carbon nanotubes, hybrid composite materials such as polymers filled with conductive particles or any other suitable material may also be used for electrodes. The electrodes can be configured to possess high electrical conductivity, low resistance, low mechanical stiffness so as to not impede the actuation behavior of the polymer, and can be chosen for their non-brittle characteristics. The electrodes can be chosen to function for multiple cycles

An electric field can be applied using a high voltage power source that is connected to the electrodes. Examples of high voltage power sources include high voltage transformers, van de Graaff generators, tesla coils, Marx generators, commercial high voltage power supplies, array(s) of capacitor banks and high voltage batteries. The applied electric field can result in an attractive force between the positive and negative electrodes known as a Maxwell force. The attractive force results in the compression of the soft elastomer that is sandwiched between the two electrodes. The attractive force results in the compression of the elastomer film in one direction and expansion of the elastomer film in the other two direction. This deformation or shape change is instant (e.g., on the order of milliseconds). Further the deformation or shape change of the elastomer is reversible upon the application and removal of the electric field. The deformation or shape change of the elastomer can result in expansion and/or contraction of the elastomer film.

In some embodiments the elastomer film can be coupled to a mechanical process such that the expansion and/or contraction of the elastomer film results in movement of mechanical components coupled to the elastomer film. In this manner the disclosed DLCE can be used as an electromechanical actuator.

In some embodiments, the DLCE fabricated according to the process illustrated in FIGS. 1 and 2 can be used as a transducer. The transducer can include at least two electrodes, and the dielectric liquid crystal elastomer. In some embodiments, the dielectric liquid crystal elastomer can have a first position that is deflected to a second position in response to a change in an electric field provided by the at least two electrodes. Further, the dielectric liquid crystal elastomer can be fabricated by pre-stretching the loosely cross-linked polydomain liquid crystal elastomer on a frame, applying UV-radiation to cross-link elements of the loosely cross-linked polydomain liquid crystal elastomer to form the dielectric liquid crystal elastomer, and removing the frame from the dielectric liquid crystal elastomer as is described in connection with FIGS. 1 and 2.

In some embodiments, the transducer can include a dielectric liquid crystal elastomer with a tensile strength between 1-100 MPa, a dielectric permittivity between about 2 and about 1000, and a thickness between about 1 micrometer and 1000 micrometer. In some embodiments the ratio of the surface area of the first position to the surface area of the second position can be between about 1 and about 15. In some embodiments, the electric field provided by the at least two electrodes in the transducer can be generated by applying a voltage of less than about 400 volts. In some embodiments, the dielectric liquid crystal elastomer is deflected from the second position to a third position in response to a second change in an electric field provided by the at least two electrodes such as by removing the electrical field or applying a different voltage across the two electrodes.

In accordance with the methods described herein, in an example, a DLCE was constructed using a ratio of monomer to spacer to crosslinker of 100% to 95% to 5%, a pre-stretch ratio (λₚ) between 1-4 under a biaxial prestretch or uniaxial compression between about 0.01-10 N, and UV radiation with a wavelength between 300-400 nm applied for 15 minutes for each side of samples under 100 micrometer thickness. The resulting DLCE had a tensile strength between about 1-10 MPa, a relative dielectric permittivity of between about 1 to 25, an actuation strain between 0-88%, and experienced a ratio of change in the surface area under an electric field of between 1 and 1.88. The resulting DLCE had a thickness between 10-100 micrometers.

Accordingly, it is envisioned that a DLCE with a tensile strength between about 1-100 MPa, relative dielectric permittivity between about 1-100000, an actuation strain between 0-2000%, a ratio of change in surface area under an electric field between about 1 to 20, and having a thickness between about 1-10000 micrometers can be formed in accordance with the disclosure herein.

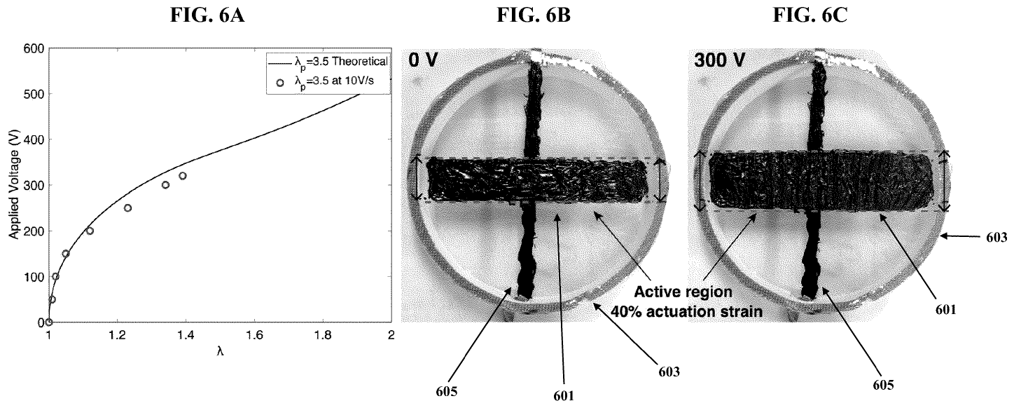

FIG. 6A-6C illustrates an example of a DLCE used as an electromechanical actuator.

FIG. 6A provides a graph of theoretical predictions of electro-actuation for a pure shear DLCE sample with a pre-stretch (i.e., λₚ=3.5) illustrated in solid lines compared with experimental results illustrated in circles measured at a voltage ramp rate of 10 V s⁻¹. In the illustrated geometry, the DLCE sample can generate ˜40% actuation strains, at an input voltage of 300 V (nominal electric field ≈15 V μm⁻¹), above which there is wrinkling and electrical breakdown. In the diaphragm configuration, the low bias pressure prevents the formation of wrinkles, and the area strain can reach a maximum of ≈88% at 400 V (nominal electric field ≈20 V μm⁻¹), before electrical breakdown (shown in FIG. 4).

FIG. 6B provides a first photograph image of a DLCE film 601 on a plastic frame 603 with a carbon grease electrode 605. The provided photograph is taken under an electric field corresponding to 0 Volts. The illustrated DLCE film 601 has a thickness of about 20 μm. As shown in FIG. 6B, a transparent DLCE sample is pre-stretched on a plastic frame, UV crosslinked and coated with conductive carbon grease electrodes on the top and bottom in a rectangular shape, similar to the pure-shear configuration.

FIG. 6C provides a second photograph image of the DLCE film 601 on a plastic frame 603. In the photograph shown in FIG. 6B, the DLCE film experiences an electric field corresponding to 300 Volts. As shown in FIG. 6C the application of the electric field results in approximately 40% actuation strain, depicted by the expansion of the DLCE film 601 in FIG. 6C when compared to FIG. 6B.

Experimental data for pure shear actuation of DLCEs illustrated in FIGS. 6A-6B were obtained by attaching free standing DLCE films on a plastic frame or rectangular acrylic plates and coating with carbon grease electrodes (MG Chemicals) on both sides to form the active actuation area. They were then connected to the high voltage DC power supply using conductive copper tapes. The input voltage was applied at a ramp rate of 10 V s⁻¹ and the actuation was recorded using a digital camera.

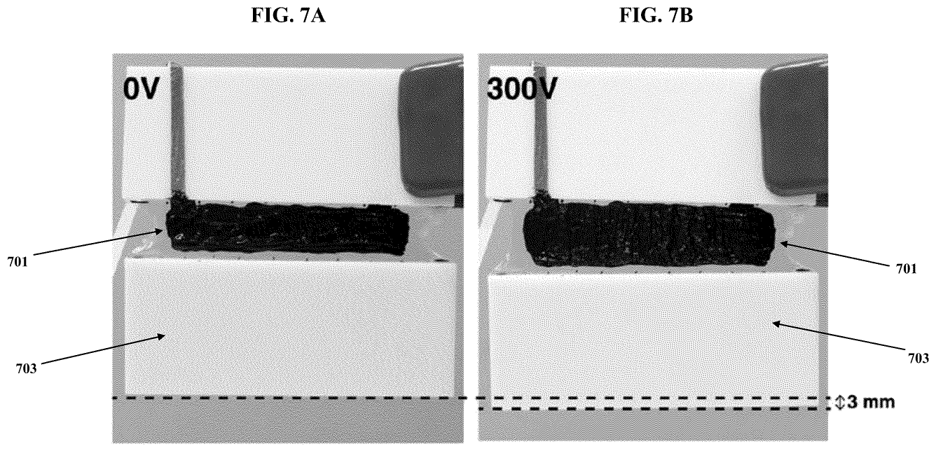

FIGS. 7A and 7B illustrate a pure shear DLCE actuator 701 lifting an acrylic plate 703. As shown, in FIG. 7A, a DLCE actuator 701 having a weight of approximately 0.012 g can be positioned adjacent to an acrylic plate. In the illustrated example, the DLCE actuator has dimensions of approximately 10 mm×55 mm×20 microns. In the illustrated example, the acrylic plate 703 weighs approximately 2.9 grams. FIG. 7A illustrates the positioning of the actuator and acrylic plate at 0 Volts. FIG. 7B illustrates that when 300 Volts is applied, the DLCE actuator 701 expands to actuate the acrylic plate 703 by approximately 3 mm.

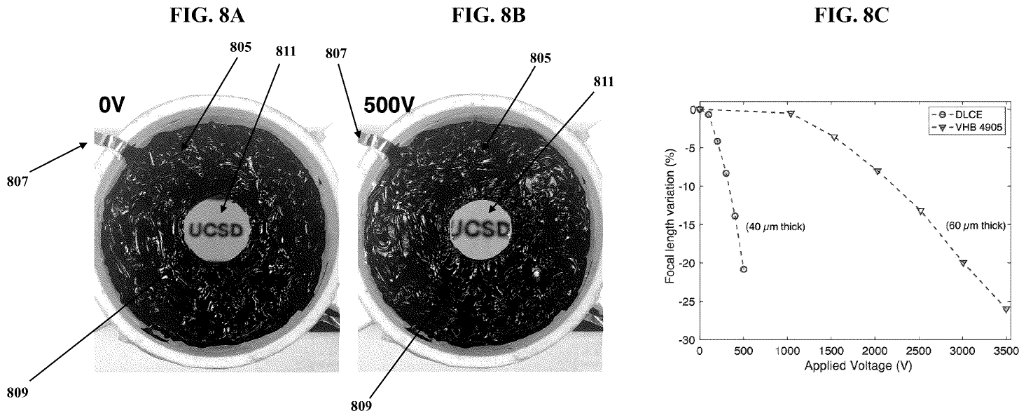

The liquid crystal based dielectric elastomer actuator described herein can be used in many applications that would benefit from low voltage technologies. Example applications include a soft tunable lens. For example FIGS. 8A-8C illustrate photographs and properties of a soft tunable lens 801. The soft tunable lens can be fabricated as follows. Two DLCE films fabricated in accordance with the processes described in FIGS. 1 and 2 can be fabricated on separate circular frames. A small volume (≈10 μL) of transparent liquid (Silicone prepolymer, Sylgard 184) can be encapsulated between the DLCE films. Conductive carbon grease can be applied on the top and bottom, in the entire area except the region of the encapsulated liquid. The electrodes can be connected to the high voltage DC power supply using conductive copper tapes and the actuation can be recorded using a digital camera. The focal length of the lens can be measured by shining a laser beam through the lens and on a movable frame. For various applied voltages, the focal length can be measured by adjusting the distance of the frame to obtain the smallest spot size.

As illustrated in FIGS. 8A and 8B, application of 500 Volts to the soft tunable lens 801 composed of two DLCE films 803 covered in conductive carbon grease 805 via copper tapes 807 modifies the focal length as shown in FIGS. 8A and 8B. The voltage induced deformation in the active region 809 encircling the transparent liquid 811, results in changing the curvature of the liquid lens, and therefore its focal length. The soft lens fabricated using DLCE, can generate a focal length change of approximately 21% at 500 V. As illustrated in FIG. 8C, the observed focal length change can be compared with that for a conventional dielectric actuator such as VHB 4905, where a voltage of 2.5 kV is required to generate similar variations.

In some embodiments, DLCE films fabricated in according to the processes described herein can be used for diaphragm actuation. For example, DLCE films fabricated according to the processes described in FIGS. 1 and 2 can be coated with carbon grease and attached to a diaphragm chamber with a 10 mm circular opening on the top. A small positive bias pressure of ≈300 Pa can be maintained in the chamber. Accordingly, applying an electric field can causes the fabricated DLCE films to deform out of plane. In one example, the active area of the DLCE film was a circle of ≈9 mm diameter. The input voltage was applied at a ramp rate of 10 V s⁻¹. The actuation was recorded using a digital camera and processed using ImageJ software. The average area strain was calculated using the following equation:

$$s = \frac{( {h}^{2} + {r}^{2} ) - ( {h}_{0}^{2} + {r}_{0}^{2} )}{( {h}_{0}^{2} + {r}_{0}^{2} )} ,$$

where hₒ and h are the initial and final height of the dome, rₒ and r are the initial and final radius of the dome, respectively.

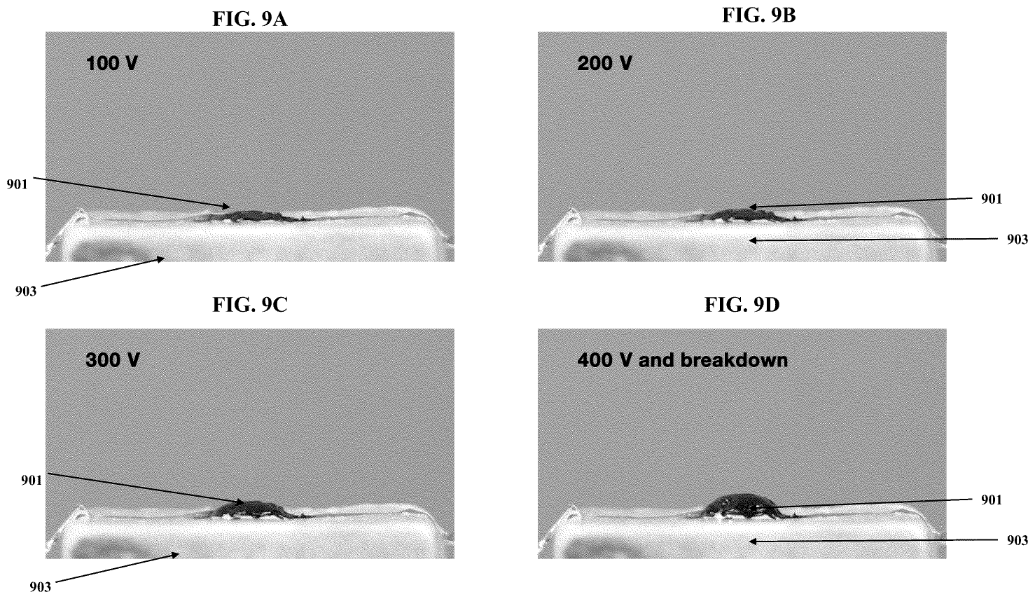

FIGS. 9A-9D provide an illustration of DLCE films fabricated for use with diaphragm actuation. As shown in FIGS. 9A-9D, a DLCE film 901 can be covered in carbon grease electrodes and formed in a circle. The circular DLCE film can be mounted on a diaphragm 903, a small container with an opening. When a gentle pressure between about 200-300 Pascals is applied at the bottom of the film, the DLCE film does not undergo deformation. However, as illustrated in FIGS. 9A-9D, as a voltage of 100 V (FIG. 9A), a voltage of 200 V (FIG. 9B), a voltage of 300 V (FIG. 9C), and a voltage of 400 V (FIG. 9D), is applied, the DLCE experiences expansion. As shown, the DLCE film expands in two directions and moves out of the plane of motion.

In some embodiments liquid crystal monomers with higher dielectric anisotropy, diverse synthetic techniques for LCE, and DE thin film fabrication techniques, can be used to fabricate various soft devices operated at a sub-100 V range. Such devices could be controlled using simple electronic circuitry, resulting in haptic and biomedical technologies that are lightweight, energy efficient, and safe. As the DLCEs disclosed herein can generate large deformations at a low voltage, they hold great potential in several applications, especially where the required driving force is low.

As described herein, in some embodiments, an electromechanical actuator developed in accordance of the processes described herein may utilize advancements in liquid crystal elastomers. For example, the electromechanical actuator described herein may allow for usage at low voltages all the while allowing for increased force output, increased energy density, increased power density and increased efficiency. In some embodiments, the electromechanical actuator described herein can be characterized as a soft actuator. In some embodiments, an electromechanical actuator built in accordance with the disclosure herein may utilize other commercial liquid crystal polymers that promote electrical activity in order to prepare dielectric liquid crystal elastomers. Similarly, in some embodiments, an electromechanical actuator built in accordance with the disclosure herein may utilize other commercial polymer chain extenders and crosslinkers that promote electrical activity.

In some embodiments, an electromechanical actuator built in accordance with the disclosure herein may be fabricated with low thickness (e.g., 10 microns or less) such that it would require voltages less than 100 Volts.

In some embodiments, a plurality of electromechanical actuators built in accordance with the disclosure herein may be stacked or coupled. For example, such an embodiment may include multiple layers of thin-film liquid crystal elastomers. Accordingly, such an embodiment may allow for the scaling and increased output force without requiring a substantial increase in the required input voltage. In some embodiments, various designs including stacked electromechanical actuators built in accordance with the disclosure herein may be designed for specific applications.

In some embodiments, the electromechanical actuator described herein can form a transducer that is integrated into other systems. For example, the electromechanical actuator described herein can be integrated into haptic devices, wearable devices, biomedical devices, prosthetics, soft robotics, power generation, adaptive optics, active braille displays, loudspeakers, deformable surfaces for optics and aerospace, energy harvesting, pumps, motors, lightweight actuators for automotive and aerospace applications, camouflage devices, microfluidics devices, soft grippers, manipulators, smart textiles, vibration damping and the like.

In some embodiments the soft electromechanical actuator can be used as a generator to harvest electrical energy from mechanical motion, forces or vibration applied to the dielectric liquid crystal elastomers.

In some embodiments the soft electromechanical actuator can be used as a sensor to detect mechanical motion, forces or vibration applied to any devices or structures by measuring the change in capacitance.

In some embodiments the soft electromechanical actuator can be used as a damper to reduce mechanical motion, forces or vibration of any devices or structures.

The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and sub-combinations of the disclosed features and/or combinations and sub-combinations of several further features disclosed above. In addition, the logic flows depicted in the accompanying figures and/or described herein do not necessarily require the particular order shown, or sequential order, to achieve desirable results. Other implementations can be within the scope of the following claims.

We claim:

1. A method for manufacturing an electromechanical actuator comprising a dielectric liquid crystal elastomer, the method comprising:
fabricating a loosely cross-linked polydomain liquid crystal elastomer;
pre-stretching the loosely cross-linked polydomain liquid crystal elastomer on a frame;
cross-linking elements of the loosely cross-linked polydomain liquid crystal elastomer to form the dielectric liquid crystal elastomer; and
removing the frame from the dielectric liquid crystal elastomer.

2. The method of claim 1, wherein fabricating the loosely cross-linked polydomain liquid crystal elastomer (LCE) further comprises:
reacting a liquid crystal monomer, a chain extender, and a cross-linker.

3. The method of claim 2, wherein the liquid crystal monomer comprises at least one of:
1,4-Bis-[4-(3-acryloyloxypropyloxy)benzoyloxy]-2-methylbenzene, 4-(6-(acryloyloxy)hexyloxy)phenyl-4-(6-(acryloyloxy)hexyloxy)benzoate, 2-methyl-1,4-phenylene bis(4-((6-(acryloyloxy)hexyl)oxy)benzoate), 6-(4-Cyano-biphenyl-4′-yloxy)hexyl acrylate, [1-phosphono-2-(1-propylpyridin-2-yl)ethyl]phosphonic acid, and 4-Cyano-4′-pentylbiphenyl, 4-((6-hydroxyhexyl)oxy)phenyl 4-((6-hydroxyhexyl)oxy)benzoate, 4-(6-acryloyloxyhexyloxy)benzoic acid, 4,4′-diacrylolylhexyloxyazobenzene, 6-[4-(4-hexyloxyphenylazo)phenoxy]hexylacrylate, 4,4′-bis[6-(acryloyloxy)hexyloxy]azobenzene, (S)-1,4-Phenylene bis(4-((S)-6-(acryloyloxy)-3-methylhexyloxy)benzoate), 4,4′-Bis(11-(acryloyloxy)undecyloxy)azobenzene, 4,4′-Bis(3-(acryloyloxy)propyloxy)azobenzene, 4,4′-Bis(6-acryloyloxyhexyloxy)azobenzene, 4,4′-Bis(9-methacryloyloxy)nonyloxy)-azobenzene, 4,4′-Bis(9-(acryloyloxy)nonyloxy)azobenzene, 4,4′-Bis(6-methacryloyloxypropyloxy)azobenzene, E-1,2-Bis(4-hex-5-enyloxyphenyl)diazene, 4,4′-Bis(11-methacryloyloxy)undecyloxy)-azobenzene, 4,4′-Bis((6-methacryloyloxy)hexyloxy)azobenzene, 4-((4-(6-(Acryloyloxy)hexyloxy)phenoxy)carbonyl)phenyl 4-(6-(acryloyloxy)hexyloxy)benzoate, 1,4-Phenylene bis(4-(6-(acryloyloxy)hexyloxy)benzoate), 6-{4-[4-(Acryloyloxy-hexyloxy)cyclohexyl]phenoxyhexyl acrylate, 4-(6-(Acryloyloxy)hexyloxy)phenyl 4-(6-(acryloyloxy)hexyloxy)-2-methylbenzoate, 1,4-Bis[4-(11-acryloyloxyundecyloxy)benzoyloxy]-2-methylbenzene, 4-((4-(3-(Acryloyloxy)propoxy)phenoxy)carbonyl)phenyl 4-(3-(acryloyloxy)propoxy)benzoate, 2-Methyl-1,4-phenylene bis(4-(3-(allyloxy)propoxy)benzoate), 4-(6-(Acryloyloxy)hexyloxy)phenyl 4-(6-(acryloyloxy)hexyloxy)benzoate, 2-Methyl-1,4-phenylene bis(4-(oct-7-enyloxy)benzoate), 4-(4-(4-(11-(Acryloyloxy)undecyloxy)benzoyloxy)cyclohexyl)phenyl 4-(11-(acryloyloxy)undecyloxy)benzoate, 4-((4-(11-(Acryloyloxy)undecyloxy)phenoxy)carbonyl)phenyl 4-(11-(acryloyloxy)undecyloxy)benzoate, 4-(4-(11-(Acryloyloxy)undecyloxy)cyclohexanecarbonyloxy)phenyl 4-(11-(acryloyloxy)undecyloxy)benzoate, 2-Methyl-1,4-phenylene bis(4-(hex-5-enyloxy)benzoate), 1,4-Bis[4-(6-acryloyloxyhexyloxy)benzoyloxy]-2-methylbenzene, 1,4-Phenylene bis(4-(10-(acryloyloxy)decyloxy)benzoate), 1,4-Phenylene bis(4-(hex-5-enyloxy)benzoate), 1,4-Bis[4-(3-acryloyloxybutyloxy)benzoyloxy]-2-methylbenzene, 1,4-Bis[4-(11-acryloyloxyundecyloxy)benzoyloxy]benzene, Acrylic acid 6-[4′-(6-acryloyloxy-hexyloxy)biphenyl-4-yloxy]hexyl ester, or (E)-4′-(6-(Methacryloyloxy)hexyloxy)biphenyl-4-yl 3-(4-methoxyphenyl)acrylate.

4. The method of claim 2, wherein the chain extender comprises at least one of 2,2′-(ethylenedioxy)diethanethiol, tetramethyldisiloxane, 1,5-diaminopentane, hexane-1,6-diyl diacrylate, bis(4-isocyanatophenyl)methane, polyethylene glycol, 1,2-ethanedithiol, 1,3-propanedithiol, 1,6-hexanedithiol, 1,9-nonanedithiol, 1,11-undecanedithiol, (ethylene glycol bis-(3-mercaptopropionate), 1,4-benzenedimethanethiol, Poly(ethylene glycol) diacrylate, 2,4,6-Triallyloxy-1,3,5-triazine, or glycol di(3-mercaptopropionate).

5. The method of claim 2, wherein the cross-linker comprises at least one of pentaerythritoltetrakis(3-mercaptopropionate), trimethylolpropane tris(3-mercaptopropionate) (TMPMP), Trimethylolpropane Trimethacrylate (TMPTMA), Pentaerythritol Triacrylate (PETA), N,N′-Methylenebisacrylamide (MBAA), 1,4-butanediol diisocyanate (BDI), toluene diisocyanate (TDI), hexamethylene diisocyanate (HDI) and isophorone diisocyanate (IPDI), Triallyl isocyanurate (TAIC), tetraethyl orthosilicate (TEOS), hexamethylene diisocyanate trimer (HDI trimer), glycidyl methacrylate (GMA), 2,4,6,8-Tetramethyl-2,4,6,8-tetravinyl cyclotetrasiloxane (TMTVCTS), 2-ethyl-2-(hydroxymethyl)propane-1,3-diol, 1,6 hexandiol diacrylate, or (1,3,5-triallyl-1,3,5-triazine-2,4,6(1H,3H,5H)-trione.

6. The method of claim 2, wherein the ratio of the liquid crystal monomer, the chain extender, to the cross-linker is selected for a molar excess of acrylate groups.

7. The method of claim 6, wherein the ratio of the liquid crystal monomer to the chain extender to the cross-linker is about 105% to about 95% to about 5%, respectively.

8. The method of claim 1, wherein pre-stretching the loosely cross-linked polydomain liquid crystal elastomer on the frame comprises equibiaxially stretching the loosely cross-linked polydomain liquid crystal elastomer.

9. The method of claim 1, wherein pre-stretching the loosely cross-linked polydomain liquid crystal elastomer on the frame comprises applying a uniaxial compression force.

10. The method of claim 1, wherein the frame comprises plastic.

11. The method of claim 1, wherein cross-linking elements of the loosely cross-linked polydomain liquid crystal elastomer to form the dielectric liquid crystal elastomer further comprises:
applying UV-radiation to cross-link elements of the loosely cross-linked polydomain liquid crystal elastomer comprises applying UV-radiation in a wavelength between about 100-400 nm, wherein applying UV-radiation to excess acrylate groups within the loosely cross-linked polydomain liquid crystal elastomer fixes the alignment of elements of the loosely cross-linked polydomain liquid crystal elastomer.

12. The method of claim 1, wherein cross-linking elements of the loosely cross-linked polydomain liquid crystal elastomer to form the dielectric liquid crystal elastomer further comprises:
applying a thermal cross-linking initiator.

13. A transducer for converting electrical energy to mechanical energy, the transducer comprising:
at least two electrodes; and
a dielectric liquid crystal elastomer having a first position that is deflected to a second position in response to a change in an electric field provided by the at least two electrodes,
wherein the dielectric liquid crystal elastomer is fabricated by pre-stretching the loosely cross-linked polydomain liquid crystal elastomer on a frame, cross-linking elements of the loosely cross-linked polydomain liquid crystal elastomer to form the dielectric liquid crystal elastomer, and removing the frame from the dielectric liquid crystal elastomer.

14. The transducer of claim 13, wherein the dielectric liquid crystal elastomer comprises tensile strength between 1-10 MPa, and relative dielectric permittivity greater than 25.

15. The transducer of claim 13, wherein the ratio of the surface area of the first position to the surface area of the second position is 2.

16. The transducer of claim 13, wherein the dielectric liquid crystal elastomer has a relative dielectric permittivity between about 2 and about 50, and the dielectric liquid crystal elastomer has a thickness between about 10 and 1000 micrometers.

17. The transducer of claim 13, wherein the electric field provided by the at least two electrodes is generated by applying voltages less than about 400 volts.

18. The transducer of claim 13, wherein the dielectric liquid crystal elastomer is deflected from the second position to a third position in response to a second change in an electric field provided by the at least two electrodes.

19. The transducer of claim 13, wherein an electrode of the at least two electrodes comprises carbon grease.

20. The transducer of claim 13, wherein the transducer is included in an artificial muscle, haptics, wearable devices, biomedical devices, robotics, power generation, adaptive optics, active braille displays, loudspeakers, deformable surfaces, energy harvesting, pumps, motors, and lightweight actuators.
